(19) United States
(12) Patent Application Publication
(10) Pub. No.: US 2012/0229148 A1
(43) Pub. Date: Sep. 13, 2012

(54) PROJECTED CAPACITIVE TOUCH PANEL HAVING A RESISTANCE FINE-TUNING STRUCTURE

(75) Inventor: Jane HSU, Taoyuan County (TW)

(73) Assignee: DerLead Investment Ltd., Taipei (TW)

(21) Appl. No.: 13/241,640

(22) Filed: Sep. 23, 2011

(30) Foreign Application Priority Data
Mar. 9, 2011 (TW) 100204155

(51) Int. Cl. G01R 27/26

(52) U.S. Cl. 324/658

(57) ABSTRACT

A projected capacitive touch panel having a resistance fine-tuning structure has an X-axis sensing layer and a Y-axis sensing layer. The X-axis sensing layer and the Y-axis sensing layer respectively have multiple X-axis electrode arrays and multiple Y-axis electrode arrays. Each X-axis electrode array or each Y-axis electrode array is composed of multiple electrodes and multiple connection portions. Each connection portion is connected between adjacent two of the electrodes of one of the X-axis or Y-axis electrode arrays. By varying widths and adjusting resistance of the connection portions of the X-axis electrode arrays and the Y-axis electrode arrays, the touch sensitivity of the touch panel can be enhanced and the size of the touch panel can be enlarged.

### BACKGROUND OF THE INVENTION

1. Field of the Invention

The present invention relates to a projected capacitive touch panel, and more particularly to a projected capacitive touch panel capable of reducing resistance or capacitance between adjacent electrodes to enhance touch sensitivity and facilitating enlargement thereof.

2. Description of the Related Art

With reference to FIG. 5, a conventional projected capacitive touch panel has a substrate 70, an X-axis sensing layer 80 and a Y-axis sensing layer 90.

The substrate 70 is transparent. The X-axis sensing layer 80 is mounted on a top surface of the substrate 70 and has multiple sensing rows horizontally aligning with each other. Each sensing row is composed of multiple rhombic X-axis electrodes 81. With reference to FIG. 6, a narrow connection portion 810 is connected between each two adjacent X-axis electrodes 81, and each sensing row is connected with an X-axis driving line 82.

The Y-axis sensing layer 90 is mounted on a bottom surface of the substrate 70 and has multiple sensing columns vertically aligning with each other. Each sensing column is composed of multiple rhombic Y-axis electrodes 91. With reference to FIG. 6, a narrow connection portion 910 is connected between each two adjacent Y-axis electrodes 91, and each sensing column is connected with a Y-axis driving line 92. Each Y-axis electrode 91 of the Y-axis sensing layer 90 either aligns directly with one of the X-axis electrodes 81 or aligns between adjacent two of the X-axis electrodes 81. With further reference to FIG. 6, each Y-axis electrode 91 of the Y-axis sensing layer 90 aligns between adjacent two of the X-axis electrodes 81.

The X-axis driving lines 82 on the X-axis sensing layer 80 and the Y-axis driving lines 92 on the Y-axis sensing layer 90 are usually formed on and alongside edges of the substrate 70 to extend to a common edge of the substrate 70, and are connected to a controller through a connection port mounted on the common edge so that the controller can detect capacitance variation of each capacitive node on the X-axis sensing layer 80 and the Y-axis sensing layer 90. Normally, projected capacitive touch panels need to have high demand for collaboration between sensing interface, such as the X-axis sensing layer 80 and Y-axis sensing layer 90, and the controller. The X-axis driving lines 82 and the Y-axis driving lines 92 are usually formed alongside edges of the substrate 70. Under this circumstance, the X-axis driving lines 82 and the Y-axis driving lines 92 to the controller are not the same and may vary significantly in length. However, the magnitudes of the wire resistance of the X-axis driving lines 82 and the Y-axis driving lines 92 are proportional to the lengths thereof. The larger the size of the touch panel is, the longer the driving lines are and the higher the wire resistance of the driving lines is. The touch sensitivity determined by the controller is affected by the increasing wire resistance, which may cause error in determining touched locations.

To solve the wire resistance issue, the internal resistance of the sensing rows and the sensing columns and the wire resistance of the X-axis driving lines 82 and the Y-axis driving lines 92 can be jointly taken into account. In other words, higher wire resistance of the X-axis driving lines 82 and the Y-axis driving lines 92 can be compensated by lower internal resistance of the sensing rows and the sensing columns, thereby solving the sensitivity issue and the size limitation of touch panels.

### SUMMARY OF THE INVENTION

An objective of the present invention is to provide a projected capacitive touch panel capable of reducing resistance or capacitance between adjacent electrodes to enhance touch sensitivity and facilitating enlargement thereof.

To achieve the foregoing objective, the projected capacitive touch panel having a resistance fine-tuning structure has a first sensing layer and a second sensing layer.

The first sensing layer has multiple first electrode arrays parallelly aligning along a first axis. Each first electrode array has multiple first electrodes and multiple first connection portions. Each first connection portion is connected between adjacent two of the first electrodes of one of the first electrode arrays and has a first width.

The second sensing layer has multiple second electrode arrays parallelly aligning along a second axis perpendicular to the first axis. Each second electrode array has multiple second electrodes and multiple second connection portions. The second electrodes are greater than the first electrodes of each first electrode array in number. Each second connection portion is connected between adjacent two of the first electrodes of one of the second electrode arrays. At least one of the second connection portions of at least one of the second electrode arrays has a second width, and the second width is greater than the first width.

In the above-mentioned touch panel each second connection portion serves as a signal transmission channel between adjacent two of the second electrodes of one of the second electrode arrays. When the second width of the second connection portion is shortened, the channel resistance of the second connection portion is reduced. Accordingly, the resistance of lengthier second electrode arrays can also be reduced, thereby raising the touch sensitivity of the touch panel and facilitating enlargement of the touch panel.

To achieve the foregoing objective, alternatively, the projected capacitive touch panel having a resistance fine-tuning structure has a first sensing layer and a second sensing layer.

The first sensing layer has multiple first electrode arrays parallelly aligning along a first axis. Each first electrode array has two first electrode sub-arrays parallelly connected and aligning along the first axis. Each first electrode sub-array has multiple first electrodes and multiple first connection portions. Each first connection portion is connected between adjacent two of the first electrodes of one of the first electrode arrays and has a first width.

The second sensing layer has multiple second electrode arrays parallelly aligning along a second axis perpendicular to the first axis. Each second electrode array has two second electrode sub-arrays parallelly connected and aligning along the second axis. Each second electrode sub-array has multiple second electrodes and multiple second connection portions. The second electrodes of each second electrode sub-array are greater than the first electrodes of each first electrode sub-array in number. Each second connection portion is connected between adjacent two of the second electrodes of one of the second electrode sub-arrays. At least one of the second connection portions of at least one of the second electrode sub-arrays has a second width, and the second width is greater than the first width.

In the above-mentioned touch panel each one of the first electrode arrays of the first sensing layer and the second electrode arrays of the second sensing layer is composed of two parallelly connected electrode sub-arrays. As the electrode sub-arrays have internal resistance, the internal resistance is reduced after the two electrode sub-arrays are parallelly connected. Moreover, each second connection portion serves as a signal transmission channel between adjacent two of the second electrodes of one of the second electrode sub-arrays. When the second width of the second connection portion is shortened, the channel resistance of the second connection portion is reduced, and the resistance of lengthier second electrode sub-arrays can also be reduced. Similarly, the touch sensitivity of the touch panel can be raised and the size of the touch panel can be enlarged.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a projected capacitive touch panel in accordance with the present invention;

FIG. 2 is an enlarged top view of the projected capacitive touch panel in FIG. 1;

FIG. 3 is a second embodiment of a projected capacitive touch panel in accordance with the present invention;

FIG. 4 is an enlarged top view of the projected capacitive touch panel in FIG. 2;

FIG. 5 is a perspective view of a conventional projected capacitive touch panel; and

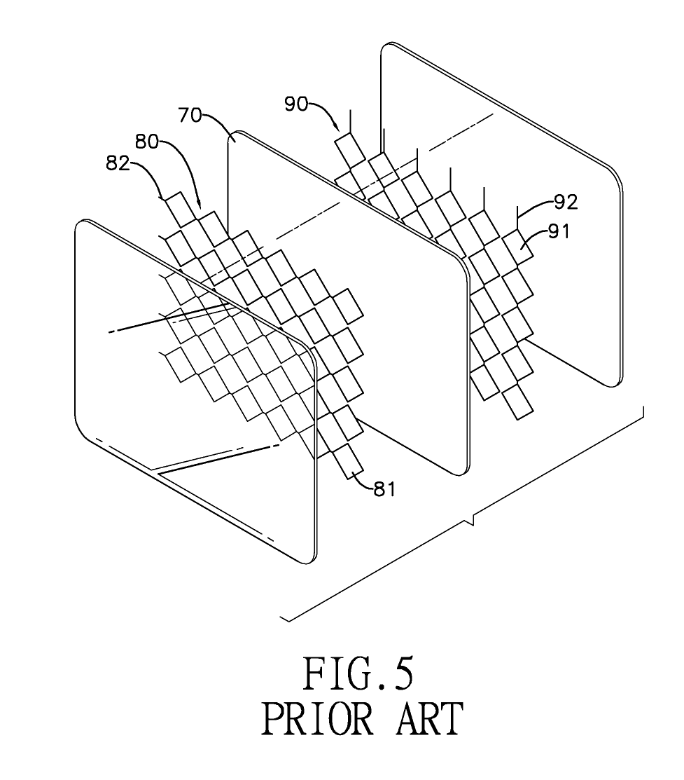

FIG. 6 is an enlarged side view of the conventional projected capacitive touch panel in FIG. 5.

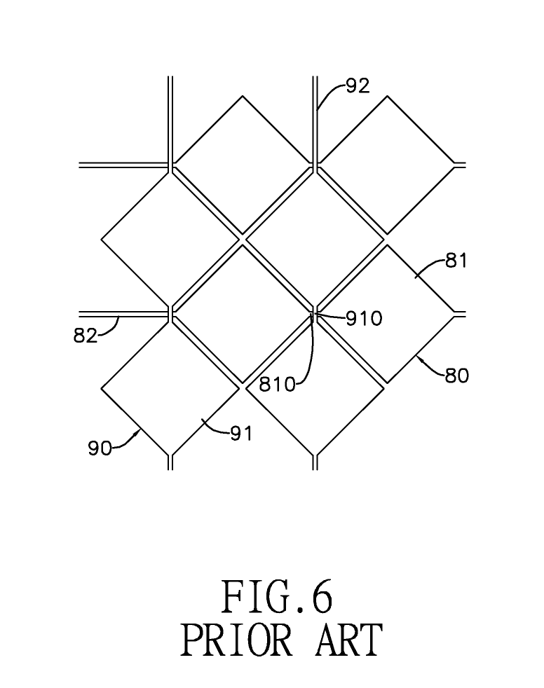

### DETAILED DESCRIPTION OF THE INVENTION

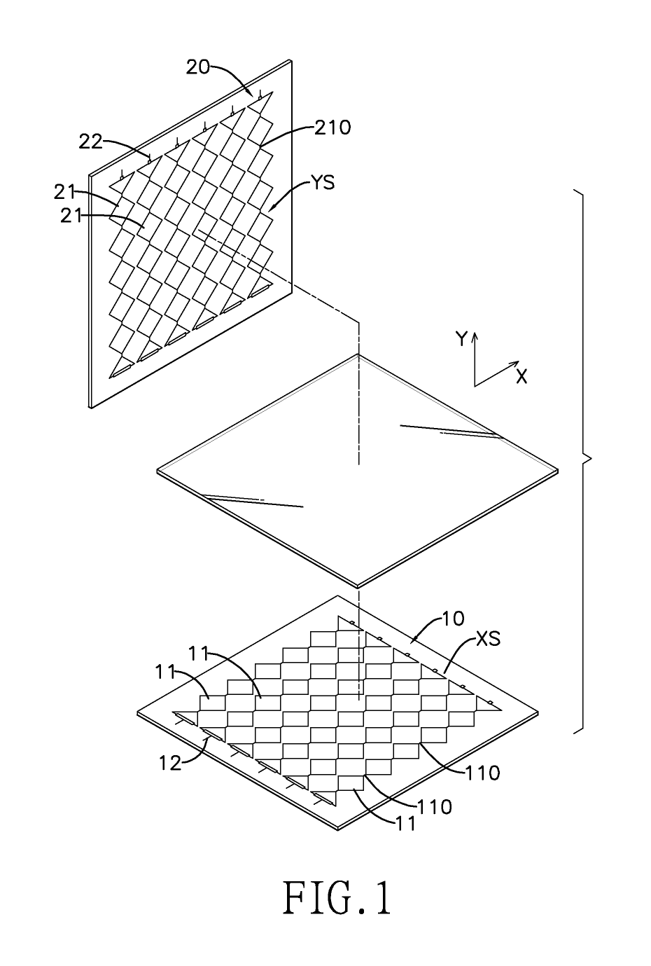

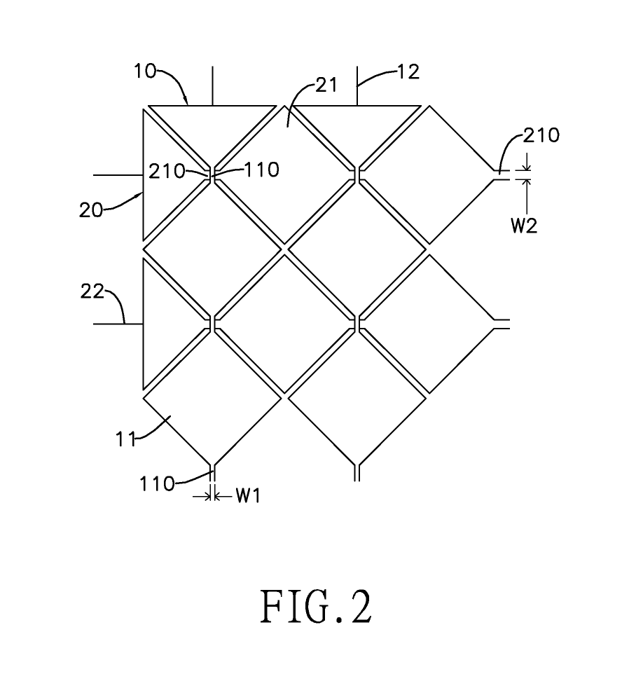

With reference to FIG. 1, a first embodiment of a projected capacitive touch panel in accordance with the present invention has at least one substrate, a first-axis sensing layer, a second-axis sensing layer and multiple connection ports. In the present embodiment, the first-axis sensing layer is an X-axis sensing layer XS, and the second-axis sensing layer is a Y-axis sensing layer YS. The X-axis sensing layer and the Y-axis sensing layer are respectively formed on a top surface and a bottom surface of a substrate or two surfaces of two substrates facing each other. The connection ports are respectively formed on the at least one substrate. The X-axis sensing layer XS has multiple X-axis electrode arrays 10 parallelly aligning along the X axis. The projected capacitive touch panel further has multiple X-axis driving lines 12 respectively formed on the at least one substrate. One end of each X-axis electrode array 10 is connected with one of the X-axis driving lines 12. Each X-axis electrode array 10 is composed of multiple X-axis electrodes 11 and multiple X-axis connection portions 110. With reference to FIG. 2, each X-axis connection portion 110 is connected between adjacent two of the X-axis electrodes 11 of one of the X-axis electrode arrays. In the present embodiment, all the X-axis connection portions 110 have a first width W1.

The Y-axis sensing layer YS has multiple Y-axis electrode arrays 20. The projected capacitive touch panel further has multiple Y-axis driving lines 22 respectively formed on the at least one substrate. One end of each Y-axis electrode array 20 is connected with one of the Y-axis driving lines 22. Each Y-axis electrode array 20 is composed of multiple Y-axis electrodes 21 and multiple Y-axis connection portions 210. The Y-axis electrodes 21 parallelly align along the Y axis, and the Y axis is perpendicular to the X axis. In the present embodiment, the Y-axis electrodes 21 of each Y-axis electrode array 20 is greater than the X-axis electrodes 11 of each X-axis electrode array 10 in number. The ratio of the number of entire X-axis electrodes 11 to that of entire Y-axis electrodes 21 may be 16:9. Each Y-axis connection portion 210 is connected between adjacent two of the Y-axis electrodes 21 of one of the Y-axis electrode arrays 20. At least one of the Y-axis connection portions 210 of at least one of the Y-axis electrode arrays 20 has a second width W2. The second width W2 is wider than the first width W1 of the X-axis connection portions 110. In the present embodiment, all Y-axis connection portions 210 of the Y-axis electrode arrays 20 have the second width W2. The ratio of the second width W2 to the first width W1 is calculated based on the ratio of the length to the width of the touch panel. For example, when the ratio of the length to the width of the touch panel is 16:9, the ratio of the second width W2 to the first width W1 is 16:9 or the second width W2 is 1.78 times as large as the first width W1.

Specifically, the X-axis connection portions 110 on the X-axis sensing layer XS remain the original width (the first width W1) while the Y-axis connection portions 210 on the Y-axis sensing layer YS have a wider width (the second width W2) relative to the first width. The Y-axis connection portions 210 bridge adjacent two of the Y-axis electrodes 21 to serve as a passage for signal transmission and has an area inversely proportional to resistance thereof. When the widths of the Y-axis connection portions 210 relatively increase, the resistance thereof relatively decreases. Hence, the issue that the touch sensitivity is affected by larger resistance arising from lengthy driving lines can be solved to facilitate enlargement of touch panels.

Besides increasing the width to all the Y-axis connection portions 210, the Y-axis connection portions 210 adjacent to the Y-axis electrode arrays 20 at specific locations can have the longer width (second width W2) and the Y-axis electrode arrays 20 at other locations can have the shorter width (first width W1). The specific locations indicate the Y-axis electrode arrays 20 connected to farther connection ports by the corresponding driving lines. The resistance of the driving lines increases due to the lengthier driving lines. Given the foregoing approach, the resistance of a Y-axis electrode array far away from its connection port can be fine-tuned.

As the Y-axis connection portions 210 on the Y-axis sensing layer YS are insulatedly overlapped by the X-axis connection portions 110 on the X-axis sensing layer XS, parasitic capacitance may occur when the Y-axis connection portions 210 and the X-axis connection portions 110 are sufficiently large to constitute two plates. To avoid generating parasitic capacitance, the first width of the X-axis connection portions can be adequately reduced when the second width W2 of the Y-axis connection portions 210 increases. As a prerequisite, such width change should not noticeably vary the resistance of the Y-axis electrode arrays and further affect their sensitivity. For example, the second width W2 of the Y-axis connection portions 210 is widened to 105% of its original width while the first width W1 of the X-axis connection portions 110 is shortened to 95% of its original width. Thus, the overlapped area of the X-axis connection portion and the Y-axis connection portion can be restored to its original state, thereby effectively avoiding the generation of parasitic capacitance. Similarly, the second width W2 of the Y-axis connection portions 210 can be widened to 110% and 115% of its original width while the first width W1 of the X-axis connection portions 110 can be shortened to 90% and 85% of its original width.

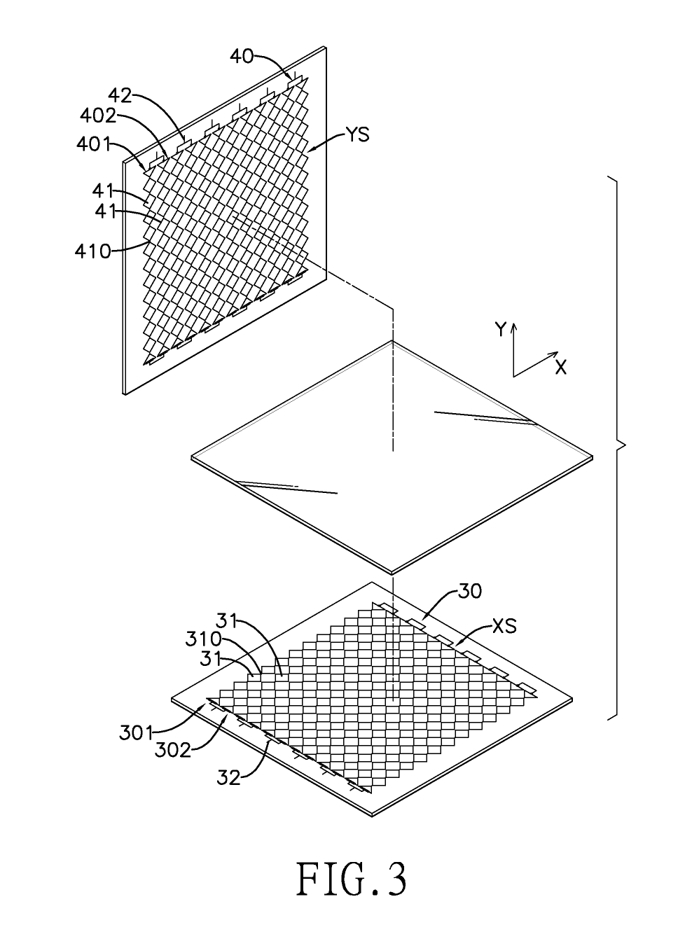

With reference to FIG. 3, a second embodiment of a projected capacitive touch panel in accordance with the present invention has at least one substrate, a first-axis sensing layer, a second-axis sensing layer and multiple connection ports. In the present embodiment, the first-axis sensing layer is an X-axis sensing layer XS, and the second-axis sensing layer is a Y-axis sensing layer YS. The X-axis sensing layer and the Y-axis sensing layer are respectively formed on a top surface and a bottom surface of a substrate or two surfaces of two substrates facing each other. The connection ports are respectively formed on the at least one substrate.

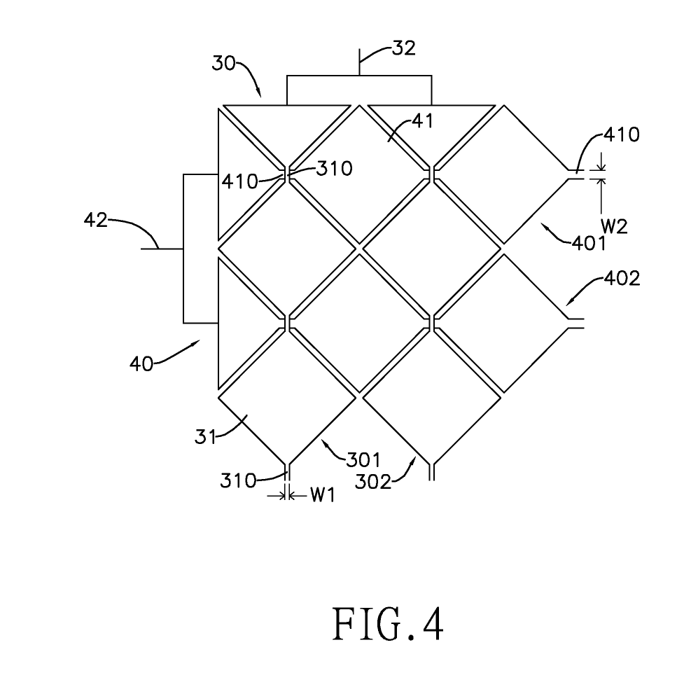

The X-axis sensing layer XS has multiple X-axis electrode arrays 30 aligning along the X axis. The projected capacitive touch panel further has multiple X-axis driving lines 32 respectively formed on the at least one substrate. One end of each X-axis electrode array 30 is connected with one of the X-axis driving lines 32. Each X-axis electrode array 30 is composed of multiple X-axis electrode sub-arrays 301, 302. In the present invention, each X-axis electrode array 30 is composed of two X-axis electrode sub-arrays 301, 302 parallelly connected and aligning along the X axis, and each X-axis electrode sub-array 301, 302 is composed of multiple X-axis electrodes 31 and multiple X-axis connection portions 310. With reference to FIG. 4, each X-axis connection portion 310 is connected between adjacent two of the X-axis electrodes 31 of one of the X-axis electrode sub-arrays 301, 302, and the X-axis connection portions 310 have a first width W1.

The Y-axis sensing layer YS has multiple Y-axis electrode arrays 40 aligning along the Y axis. The projected capacitive touch panel further has multiple Y-axis driving lines 42 respectively formed on the at least one substrate. One end of each Y-axis electrode array 40 is connected with one of the Y-axis driving lines 42. Each Y-axis electrode array 40 is composed of multiple Y-axis electrode sub-arrays 401, 402. In the present invention, each Y-axis electrode array 40 is composed of two Y-axis electrode sub-arrays 401, 402 parallelly connected and aligning along the Y axis, and each Y-axis electrode sub-array 401, 402 is composed of multiple Y-axis electrodes 41 and multiple Y-axis connection portions 410. Each Y-axis connection portion 410 is connected between adjacent two of the Y-axis electrodes 41 of one of the Y-axis electrode sub-arrays 401, 402. Similar to the first embodiment, the Y-axis connection portions 410 of all or part of the Y-axis electrode sub-arrays 401, 402 have a second width W2, and the second width W2 is greater than the first width W1 of the X-axis connection portions 310.

According to parallel resistance formula, the resistance value of two parallelly connected resistors is less than the resistance value of any of the resistors alone. Moreover, the X-axis and Y-axis electrode sub-arrays 301, 302, 401, 402 are made of Indium Tin Oxide (ITO) and have internal resistance existing therein. Hence, the parallelly connected X-axis electrode sub-arrays 301, 302 of each X-axis electrode array 30 and the parallelly connected Y-axis electrode sub-arrays 401, 402 of each Y-axis electrode array 40 cause the resistance values of the X-axis electrode arrays 30 and the Y-axis electrode arrays 40 to be reduced. Additionally, the Y-axis connection portions 410 connected with the Y-axis electrode arrays 40 are widened to further lower the resistance values of all or part of the Y-axis electrode arrays 40. Accordingly, the touch sensitivity can be effectively enhanced.

Similar to the first embodiment, to avoid generating parasitic capacitance, the widths of all or part of the X-axis connection portions 310 of the X-axis electrode arrays 30 can be adequately reduced.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A projected capacitive touch panel having a resistance fine-tuning structure, comprising:
a first sensing layer having:
multiple first electrode arrays parallelly aligning along a first axis, each first electrode array having:
multiple first electrodes; and
multiple first connection portions, each first connection portion connected between adjacent two of the first electrodes of one of the first electrode arrays and having a first width;
a second sensing layer having:
multiple second electrode arrays parallelly aligning along a second axis perpendicular to the first axis, each second electrode array having:
multiple second electrodes being greater than the first electrodes of each first electrode array in number; and
multiple second connection portions, each second connection portion connected between adjacent two of the first electrodes of one of the second electrode arrays, wherein at least one of the second connection portions of at least one of the second electrode arrays has a second width, and the second width is greater than the first width.

2. The projected capacitive touch panel as claimed in claim 1, wherein the second connection portions of each second electrode array have the second width.

3. The projected capacitive touch panel as claimed in claim 1 further comprising one substrate, wherein the first sensing layer and the second sensing layer are respectively formed on a top surface and a bottom surface of the substrate.

4. The projected capacitive touch panel as claimed in claim 1 further comprising two substrates, wherein the first sensing layer and the second sensing layer are respectively formed on two surfaces of the substrates facing each other.

5. The projected capacitive touch panel as claimed in claim 2, wherein a ratio of the second width to the first width is 16 to 9.

6. The projected capacitive touch panel as claimed in claim 2, wherein the second width is widened to 105% of an original width thereof, and the first width is shortened to 95% of an original width thereof.

7. The projected capacitive touch panel as claimed in claim 2, wherein the second width is widened to 110% of an original width thereof, and the first width is shortened to 90% of an original width thereof.

8. The projected capacitive touch panel as claimed in claim 2, wherein the second width is widened to 115% of an original width thereof, and the first width is shortened to 85% of an original width thereof.

9. A projected capacitive touch panel having a resistance fine-tuning structure, comprising:
a first sensing layer having:
multiple first electrode arrays parallelly aligning along a first axis, each first electrode array having:
two first electrode sub-arrays parallelly connected and aligning along the first axis, each first electrode sub-array having:
multiple first electrodes; and
multiple first connection portions, each first connection portion connected between adjacent two of the first electrodes of one of the first electrode arrays and having a first width;
a second sensing layer having:
multiple second electrode arrays parallelly aligning along a second axis perpendicular to the first axis, each second electrode array having:
two second electrode sub-arrays parallelly connected and aligning along the second axis, each second electrode sub-array having:
multiple second electrodes, wherein the second electrodes of each second electrode sub-array are greater than the first electrodes of each first electrode sub-array in number; and
multiple second connection portions, each second connection portion connected between adjacent two of the second electrodes of one of the second electrode sub-arrays, wherein at least one of the second connection portions of at least one of the second electrode sub-arrays has a second width, and the second width is greater than the first width.

10. The projected capacitive touch panel as claimed in claim 9, wherein the second connection portions of each second electrode sub-array have the second width.

11. The projected capacitive touch panel as claimed in claim 9 further comprising one substrate, wherein the first sensing layer and the second sensing layer are respectively formed on a top surface and a bottom surface of the substrate.

12. The projected capacitive touch panel as claimed in claim 9 further comprising two substrates, wherein the first sensing layer and the second sensing layer are respectively formed on two surfaces of the substrates facing each other.

13. The projected capacitive touch panel as claimed in claim 10, wherein a ratio of the second width to the first width is 16 to 9.

14. The projected capacitive touch panel as claimed in claim 10, wherein the second width is widened to 105% of an original width thereof, and the first width is shortened to 95% of an original width thereof.

15. The projected capacitive touch panel as claimed in claim 10, wherein the second width is widened to 110% of an original width thereof, and the first width is shortened to 90% of an original width thereof.

16. The projected capacitive touch panel as claimed in claim 10, wherein the second width is widened to 115% of an original width thereof, and the first width is shortened to 85% of an original width thereof.
